(19) United States
(12) Patent Application Publication
(10) Pub. No.: US 2004/0212430 A1
(43) Pub. Date: Oct. 28, 2004

(54) Common-mode current-feedback circuitry

(76) Inventors: Pricilla Eseobar-Bowser, Plano, TX (US); Maria-Flora Carreto, Richardson, TX (US)

Correspondence Address: TEXAS INSTRUMENTS INCORPORATED, P O BOX 655474, M/S 3999, DALLAS, TX, 75265

(21) Appl. No.: 10/422,669

(22) Filed: Apr. 24, 2003

(51) Int. Cl. H03F 3/45

(52) U.S. Cl. 330/259

(57) ABSTRACT

Disclosed is a common-mode current feedback circuit 32 and associated systems 39 and methods 49. The circuit 32 has a differential pair of bipolar transistors Q29, Q30 to accept input from the amplifier output voltage nodes Vₒᵤₜ₋, Vₒᵤₜ₊. The differential pair of transistors Q29, Q30 are coupled to a current comparator 32. The current comparator 34 is adapted to provide stabilizing current I_{ctrl} in response to detection of a differential in amplifier output voltages Vₒᵤₜ₋, Vₒᵤₜ₊.

### TECHNICAL FIELD

The invention relates to electronic circuits. More particularly, the invention relates to circuitry for providing common-mode current feedback for stabilizing fully differential amplifier circuits.

### BACKGROUND OF THE INVENTION

Many high performance analog integrated circuits currently in use in the arts make use of fully differential signal paths. When employing operational amplifiers, this approach involves the use of differential outputs as well as differential inputs, such op amps are generally referred to as fully differential amplifiers. Fully differential amplifiers are often used for their low susceptibility to noise from the substrate and from other sources such as the switching of pass-transistor switches in switched-capacitor applications.

The use of fully differential amplifiers can be disadvantaged in some applications by the requirement of also using common-mode feedback circuitry to provide stability. Typically, the common-mode loop gain in a fully differential amplifier circuit is not large enough to control its voltage. Thus, a common-mode feedback of voltage into the circuit is generally used to prevent drift.

A common-mode feedback circuit known in the arts is portrayed in FIG. 1 (prior art). The fully differential amplifier circuit 10 has differential inputs labeled IN+ and IN−. Two differential outputs, labeled V out+ and Vout− are both sensed by a common-mode feedback circuit, CMFB, so that a control voltage V_{ctrl} may be fed back to the circuit 10 in order to maintain the common-mode voltage of the amplifier circuit 10 at a pre-selected stabilizing value, usually close to the middle of its acceptable operating range, or “midrail”.

The CMFB circuitry, represented by a “black box” in FIG. 1 (prior art), must be designed with great care in order to ensure proper operation of the amplifier circuit 10. Various CMFB designs are known in the arts, but available designs are limited to use with amplifier circuits operating in the voltage-mode. For example, a fully differential class AB amplifier input circuit 20 known in the arts, as shown in FIG. 2 (prior art), cannot be stabilized using a conventional voltage-mode CMFB circuit as shown in the example of FIG. 1 (prior art).

A common-mode current feedback circuit capable of stabilizing amplifier circuits in current-mode operation, would be useful in the arts. Such a common-mode current feedback circuit would provide advantages, including but not limited to increased signal processing speed, and decreased amplifier circuit design cost.

### SUMMARY OF THE INVENTION

In carrying out the principles of the present invention, in accordance with embodiments thereof, amplifier circuits are stabilized using a common-mode current feedback circuit.

According to one aspect of the invention, a common-mode current feedback circuit has a differential pair of transistors coupled to a current comparator. The current comparator is adapted to provide stabilizing input current to an amplifier circuit responsive to a differential in amplifier output voltages.

According to another aspect of the invention, a method of stabilizing inputs to a fully differential amplifier circuit includes a step of monitoring the magnitudes of the amplifier output signals. A step of providing stabilizing currents to high-impedance nodes of the amplifier circuit outputs is implemented responsive to a differential in amplifier output voltage magnitude.

According to another aspect of the invention, a fully-differential amplifier system includes a bipolar transistor common-mode current feedback circuit coupled to the differential outputs of the amplifier circuit and including a current comparator feedback to stabilize the amplifier inputs.

The invention provides technical advantages including but not limited to common-mode current feedback amplifier circuit stabilization and related increased signal processing speed. These and other features, advantages, and benefits of the present invention will become apparent to one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (prior art) depicts an example of a common-mode feedback circuit according to the prior art;

FIG. 2 (prior art) is an example of an amplifier circuit according to the prior art with which the common-mode current feedback circuit of the invention may be advantageously used;

FIG. 3 is an example of a common-mode current feedback circuit according to an embodiment of the invention;

FIG. 4 is an example illustrating the use of the embodiment of the common-mode current feedback circuit of FIG. 3 with the prior art amplifier circuit of FIG. 2; and

FIG. 5 is a process flow diagram illustrating an example of a preferred method according to the invention.

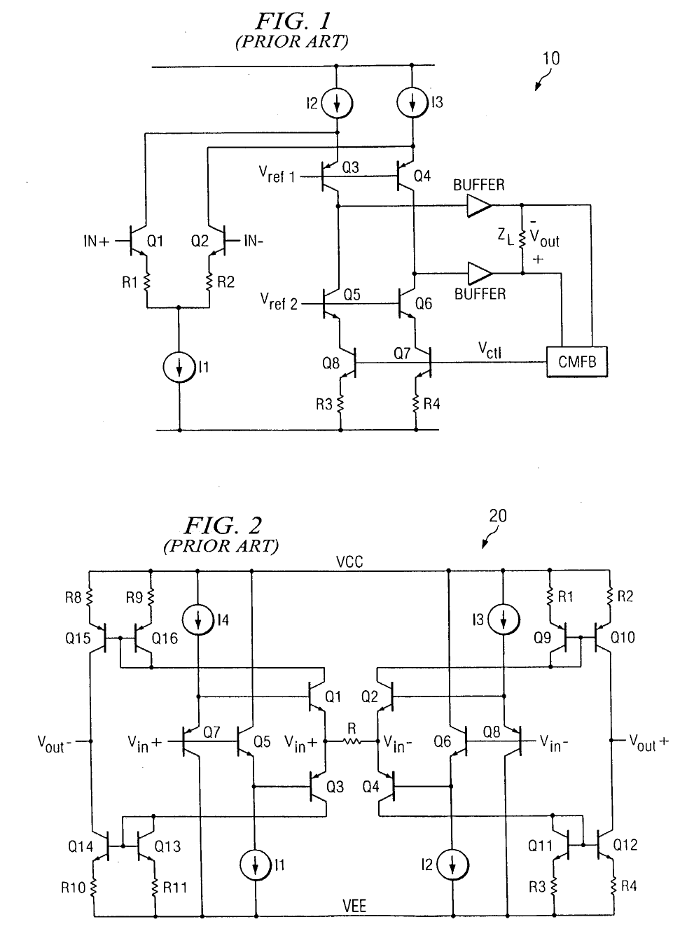

References in the detailed description correspond to like references in the figures unless otherwise noted. Like numerals refer to like parts throughout the various figures. Descriptive and directional terms used in the written description such as upper, lower, left, right, etc., refer to the drawings themselves as laid out on the paper and not to physical limitations of the invention unless specifically noted. The drawings are not to scale, and some features of embodiments shown and discussed are simplified or exaggerated for illustrating the principles, features, and advantages of the invention.

### DETAILED DESCRIPTION OF PREFERRED EMBODIMENTS

In general, the invention provides circuits, systems, and associated methods used for monitoring differential output voltages of an amplifier circuit and responsively providing stabilizing input currents to the amplifier circuit when beneficial for stability.

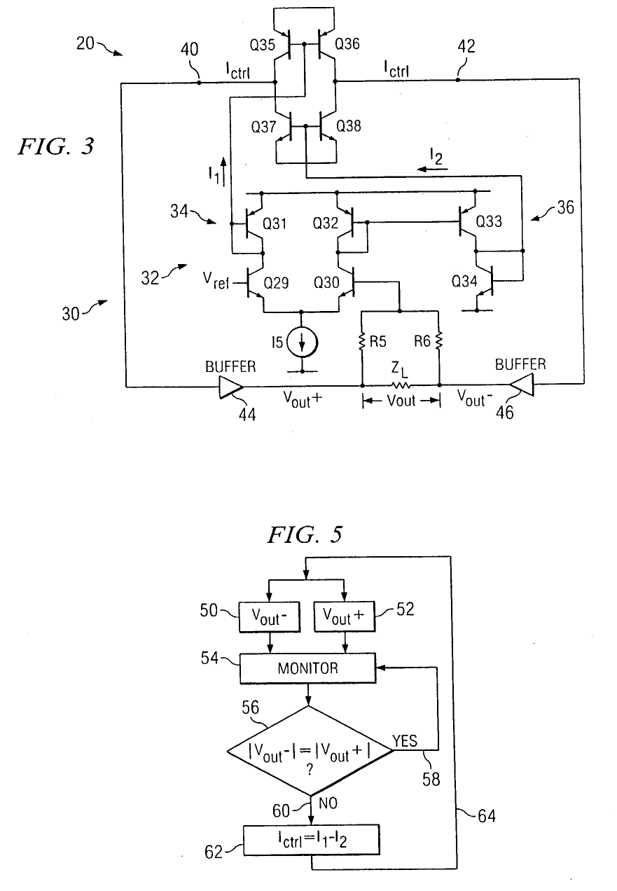

Initially referring primarily to FIG. 3, a preferred embodiment of a common-mode current feedback circuit 30 of the invention is described. It is at first assumed for the sake of this example that Vₒᵤₜ₊ is equal in magnitude to Vₒᵤₜ₋, and that the common-mode output voltage is zero. Assuming an ideal case for purposes of this example, where a differential pair of transistors Q29, Q30, has infinite common-mode input rejection, the large-signal output of the differential transistor pair, Q29, Q30, depends only on the input voltage differential in the magnitudes of Vₒᵤₜ₊ and Vₒᵤₜ₋. Thus, the average of both outputs, Vₒᵤₜ₊, Vₒᵤₜ₋, is applied at differential input transistor Q30 of the common-mode current feedback circuit 30, and a reference voltage V_{ref}, preferably a midrail value, is applied to the other differential input transistor Q29.

Preferably, the common-mode current feedback circuit 30 has a comparator circuit 32. The comparator 32, preferably uses current mirrors 34, 36. The first current mirror configuration 34, is implemented in this example with Q35, and Q36, coupled to the input transistor Q29 with diode-transistor Q31. The first current mirror 34 is opposed by the second current mirror configuration 36 of transistors Q34, Q37, Q38, coupled to input transistor Q30 by Q32 and Q33. A first high-impedance node 40 is shown to illustrate the junction of the current comparator 32 output with Vₒᵤₜ₊. A second high-impedance node 42 is shown at the opposing junction of the comparator circuit 32 with Vₒᵤₜ₋. Output voltages Vₒᵤₜ₊ and Vₒᵤₜ₋ are buffered at buffers 44 and 46 respectively, tied to the differential input transistor Q30, completing the loop.

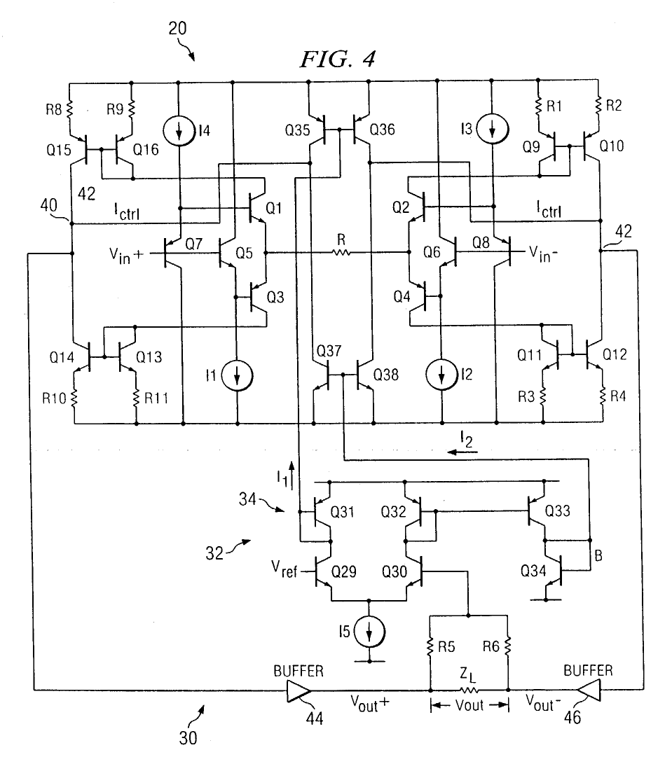

Now referring primarily to FIG. 4, consideration of two possible operational scenarios may be helpful to the understanding of the invention. A class AB amplifier input circuit 20 familiar in the arts is shown operably coupled to a common-mode current feedback circuit 30 according to the invention.

Under one possible operational scenario, the two differential output voltages Vₒᵤₜ₊ and Vₒᵤₜ₋ are equal in magnitude. In such a case, the current at transistor Q29 is equal to the current at transistor Q30. In this instance, the current comparator 32 does not transmit current I_{ctrl} to the high-impedance nodes 40, 42.

Under the other possible operational scenario, the effects of a mismatch in the magnitudes of the output voltages Vₒᵤₜ₊ and Vₒᵤₜ₋ is considered. The currents in the diode-connected transistors, Q31 and Q 32, are unequal. The result is the transmission of currents, herein denominated I₁ and I₂ respectively. Thus, a stabilizing current, I_{ctrl}=I₁−I₂, is transmitted to the high-impedance nodes 40, 42, adjusting the common-mode voltage Vₒᵤₜ of the amplifier circuit 20. As a consequence of this common-mode current feedback I_{ctrl}, the amplifier circuit 20 inputs, Vᵢₙ₊ and Vᵢₙ₋, are stabilized.

An alternative graphical representation of an exemplary preferred embodiment of the invention is presented in the process flow diagram of FIG. 5. Central to the providing of common-mode current feedback, the differential output voltages Vₒᵤₜ₋ 50 and Vₒᵤₜ₊ 52 are monitored 54 by the CMCF circuit. In a comparing step 56, the monitored differential output voltages are compared in terms of their magnitudes. As indicated by arrow path 58, in the event that the Vₒᵤₜ₋ and Vₒᵤₜ₊ magnitudes are equal, monitoring 54 continues without additional feedback. Alternatively, as indicated by arrow path 60, in the event that the magnitudes of Vₒᵤₜ₋ and Vₒᵤₜ₊ are unequal, a stabilizing, or control current, I_{ctrl}=I₁−I₂, is generated, step 62. Shown at arrow path 64, the control current I_{ctrl} is fed back into the circuit.

Thus, the invention provides common-mode current feedback stabilization for increased current-mode amplifier circuit operating speeds. While the invention has been described with reference to certain illustrative embodiments, the description of the methods and devices described are not intended to be construed in a limiting sense. Various modifications of the illustrative embodiments, such as for example, the substitution of alternative transistor types, as well as other advantages and embodiments of the invention will be apparent to persons skilled in the art upon reference to the description and claims.

1. A common-mode current feedback circuit comprising:
a differential pair of first and second input transistors having substantially infinite common-mode rejection;
a current comparator operably coupled to the differential pair, the current comparator adapted to provide stabilizing current feedback responsive to a common-mode output differential voltage.

2. A circuit according to claim 1 wherein the differential pair of input transistors further comprises:
a first bipolar transistor having a base coupled to a voltage reference node, and an emitter coupled to a current source; and
a second bipolar transistor having a base coupled to a differential voltage output node, and an emitter coupled to the current source.

3. A common-mode current feedback circuit comprising:
a differential pair of first and second input transistors having substantially infinite common-mode rejection:
a current comparator operably coupled to the differential pair, the current comparator adapted to provide stabilizing current feedback responsive to a common-mode output differential voltage:
a first bipolar transistor having a base coupled to a voltage reference node, and an emitter coupled to a current source;
a second bipolar transistor having a base coupled to a differential voltage output node, and an emitter coupled to the current source;
a third bipolar transistor adapted to function as a diode coupled to the collector of the first bipolar transistor; and
a fourth bipolar transistor adapted to function as a diode coupled to the collector of the second bipolar transistor.

4. A common-mode current feedback circuit comprising:
a differential pair of first and second input transistors having substantially infinite common-mode rejection: and
a current comparator operably coupled to the differential pair, the current comparator adapted to provide stabilizing current feedback responsive to a common-mode output differential voltage;
wherein the current comparator further comprises:
a first current mirror operably coupled to the first input transistor; and
a second current mirror operably coupled to the second input transistor.

5. A circuit according to claim 4 wherein the first current mirror further comprises:
a third bipolar transistor having a base and collector coupled together;
a fifth bipolar transistor having a base coupled to the base of the third bipolar transistor, an emitter coupled to a first voltage node, and a collector coupled to a first high-impedance output node; and
a sixth bipolar transistor having a base coupled to the base of the fifth bipolar transistor, an emitter coupled to the first voltage node, and a collector coupled to a second high-impedance output node.

6. A circuit according to claim 4 wherein the second current mirror further comprises:
a seventh bipolar transistor having a base coupled to the base of the fourth bipolar transistor;
an eight bipolar transistor having a base and collector coupled together, the collector also coupled to the collector of the seventh bipolar transistor;
a ninth bipolar transistor having a base coupled to the base of the eighth bipolar transistor, an emitter coupled to a second voltage node, and a collector coupled to a first high-impedance output node; and
a tenth bipolar transistor having a base coupled to the base of the ninth bipolar transistor, an emitter coupled to the second voltage node, and a collector coupled to a second high-impedance output node.

7. A common-mode current feedback circuit comprising:
a first bipolar transistor having a base coupled to a voltage reference node, and an emitter coupled to a current source; and
a second bipolar transistor having a base coupled to a differential voltage output node, and an emitter coupled to the current source;
a third bipolar transistor having a base and collector coupled together;
a fourth bipolar transistor having a base and collector coupled together;
a fifth bipolar transistor having a base coupled to the base of the third bipolar transistor, an emitter coupled to a first voltage node, and a collector coupled to a first high-impedance output node;
a sixth bipolar transistor having a base coupled to the base of the fifth bipolar transistor, an emitter coupled to the first voltage node, and a collector coupled to a second high-impedance output node;
a seventh bipolar transistor having a base coupled to the base of the fourth bipolar transistor;
an eighth bipolar transistor having a base and collector coupled together, the base of the eight bipolar transistor also coupled to the collector of the seventh bipolar transistor;
a ninth bipolar transistor having a base coupled to the base of the eighth bipolar transistor, an emitter coupled to a second voltage node, and a collector coupled to the first high-impedance output node; and
a tenth bipolar transistor having a base coupled to the base of the ninth bipolar transistor, an emitter coupled to the second voltage node, and a collector coupled to the second high-impedance output node;
wherein the first and second high-impedance output nodes are adapted to provide current feedback to the a differential voltage output node.

8. A common-mode current feedback circuit according to claim 7 wherein the first, second, eighth, ninth, and tenth, bipolar transistors consist of NPN transistors, and the third, fourth, fifth, sixth, and seventh bipolar transistors consist of PNP transistors.

9. (cancelled).

10. A method of stabilizing input to a fully differential amplifier circuit comprising the steps of:
monitoring the relative magnitudes of two differential amplifier output voltages;
responsive to a difference in the relative magnitudes of two differential amplifier output voltages, providing stabilizing current to the amplifier common-mode voltage wherein the steps of monitoring and providing stabilizing current further comprise steps of performing a comparison of two currents as a function of the two differential amplifier output voltages.

11. A fully differential current-mode amplifier system comprising:
an amplifier circuit having two differential input nodes and two output nodes;
a bipolar transistor common-mode current feedback circuit coupled to the two output nodes, the common mode current feedback circuit adapted to provide stabilizing current to a common-mode voltage of the amplifier circuit responsive to voltages at the output nodes.

12. A fully differential current-mode amplifier system according to claim 11 wherein the bipolar transistor common-mode current feedback circuit further comprises:
a differential pair of first and second input transistors having substantially infinite common-mode rejection;
a current comparator operably coupled to the differential pair, the current comparator adapted to provide stabilizing current responsive to a common-mode input differential voltage.

13. A fully differential current-mode amplifier system according to claim 12 wherein the differential pair of input transistors further comprises:
a first bipolar transistor having a base coupled to a voltage reference node, and an emitter coupled to a current source; and
a second bipolar transistor having a base coupled to a differential voltage output node, and an emitter coupled to the current source.

14. A fully differential current-mode amplifier system comprising:
an amplifier circuit having two differential input nodes and two output nodes;
a bipolar transistor common-mode current feedback circuit coupled to the two output nodes the common mode current feedback circuit adapted to provide stabilizing current to a common-mode voltage of the amplifier circuit responsive to voltages at the output nodes,
wherein the bipolar transistor common-mode current feedback circuit further comprises:
a differential pair of first and second input transistors having substantially infinite common-mode rejection;
a current comparator operably coupled to the differential pair, the current comparator adapted to provide stabilizing current responsive to a common-mode input differential voltage.
wherein the current comparator further comprises:
a first current mirror operably coupled to the first input transistor; and
a second current mirror operably coupled to the second input transistor.

15. A fully differential current-mode amplifier system according to claim 14 wherein the first current mirror further comprises:
a third bipolar transistor having a base and collector coupled together;
a fifth bipolar transistor having a base coupled to the base of the third bipolar transistor, an emitter coupled to a first voltage node, and a collector coupled to a first high-impedance output node; and
a sixth bipolar transistor having a base coupled to the base of the fifth bipolar transistor, an emitter coupled to the first voltage node, and a collector coupled to a second high-impedance output node.

16. A fully differential current-mode amplifier system according to claim 14 wherein the second current mirror further comprises:
a seventh bipolar transistor having a base coupled to the base of the fourth bipolar transistor;
an eight bipolar transistor having a base and collector coupled together, the collector also coupled to the collector of the seventh bipolar transistor;
a ninth bipolar transistor having a base coupled to the base of the eighth bipolar transistor, an emitter coupled to a second voltage node, and a collector coupled to a first high-impedance output node; and
a tenth bipolar transistor having a base coupled to the base of the ninth bipolar transistor, an emitter coupled to the second voltage node, and a collector coupled to a second high-impedance output node.
